(19) United States
(12) Patent Application Publication
(10) Pub. No.: US 2024/0224504 A1
(43) Pub. Date: Jul. 4, 2024

(54) DYNAMIC RANDOM-ACCESS MEMORY USING WIDE BAND GAP MATERIALS

(71) Applicant: Intel Corporation, Santa Clara, CA (US)

(72) Inventors: Abhishek Anil SHARMA, Portland, OR (US); Han Wui THEN, Portland, OR (US); Pushkar RANADE, San Jose, CA (US); Wilfred GOMES, Portland, OR (US); Sagar SUTHRAM, Portland, OR (US); Tahir GHANI, Portland, OR (US); Anand S. MURTHY, Portland, OR (US)

(21) Appl. No.: 18/089,957

(22) Filed: Dec. 28, 2022

(51) Int. Cl. H10B 12/00

(52) U.S. Cl. CPC H01L 27/1082; H01L 27/10873; H01L 29/1608

(57) ABSTRACT

Embodiments described herein may be related to apparatuses, processes, systems, and/or techniques for fabricating semiconductor packages that include DRAM using wide band gap materials, such as SiC or GaN to reduce transistor leakage. In addition, transistors may be fabricated adding one or more extra layers between a source and a drain of a transistor and the contact of the source of the drain to increase the effective electrical gate length of the transistor to further reduce leakage. In addition, for these transistors, a thickness of the body below the gate may be made narrow to improve gate control. Other embodiments may be described and/or claimed.

### FIELD

Embodiments of the present disclosure generally relate to the field of semiconductor manufacturing, and in particular to packages that include dynamic random-access memory (DRAM).

### BACKGROUND

Continued growth in virtual machines, cloud computing, and portable devices will continue to increase the demand for high density transistors within chips and packages. This is particularly true with compute dies that are interacting with large amounts of memory for high bandwidth (HBW) computing, where increased amounts of power and memory may be required for operation.

### BRIEF DESCRIPTION OF THE DRAWINGS

FIG. 1 shows cross-section side views of a diagram of a semiconductor package that includes DRAM within a silicon carbide (SiC) layer or a gallium nitride (GaN) layer of the package, in accordance with various embodiments.

FIG. 2 shows cross-section side views of a diagram of a semiconductor package that includes DRAM that includes three capacitors within a SiC layer or a GaN layer of the package, in accordance with various embodiments.

FIGS. 3A-3E show cross-section side views of various transistors that include additional layers between the transistor body and a source or drain contact, where the additional layers include SiC or GaN, in accordance with various embodiments.

FIG. 4 illustrates a side view of a diagram of a wafer scale engine (WSE) that includes Zetta memory that is powered by high voltage input that is converted using devices within a SiC layer coupled with devices within a wide band gap layer, in accordance with various embodiments.

FIG. 5 illustrates an example process for creating a package that includes transistors that include additional layers between the transistor body and a source or drain contact, where the additional layers include SiC or GaN, in accordance with various embodiments.

FIG. 6 illustrates a computing device in accordance with one implementation of the invention.

FIG. 7 illustrates an interposer that includes one or more embodiments of the invention.

FIG. 8A illustrates a computing device in accordance with one implementation of an embodiment of the present disclosure.

FIG. 8B illustrates a processing device in accordance with one implementation of an embodiment of the present disclosure.

### DETAILED DESCRIPTION

Embodiments described herein may be related to apparatuses, processes, systems, and/or techniques for fabricating semiconductor packages that include DRAM using wide band gap materials, such as SiC or GaN. In embodiments, wide band gap materials may be materials with a band gap greater than two electron volts. DRAM memory may be built using a transistor that is electrically coupled with one or more capacitors. The performance of the DRAM may be enhanced by using transistors that have low leakage characteristics, which may be achieved by implementing transistors in a wide band gap material.

In embodiments, transistors that are part of DRAM memory may be improved by adding one or more extra layers between a source and a drain of a transistor and the contact of the source of the drain. By adding additional layers, in particular using wide band gap materials such as SiC or GaN, the effective electrical gate length of the transistor may be increased thus reducing leakage for the transistor. In embodiments, by making the body, or channel, of the transistor beneath the gate narrower, this may improve gate control.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

In embodiments, high-Tc conductors are utilized for global routing. Implementation of embodiments described herein can include the presence of such materials in a metal layer and/or at the package level. Implementation of embodiments described herein can include the fabrication of inductors and/or through silicon vias (TSVs) with the same. Implementation of embodiments described herein can include fabrication of a separate metal stack (bonded or monolithic) for custom routing of finished product wafers. Implementation of embodiments described herein can include the introduction of high Tc superconductors (single crystal or deposited—atomic layer deposition (ALD) and/or chemical vapor deposition (CVD) may be used to reduce the IR drop across long distances including between die stitching.

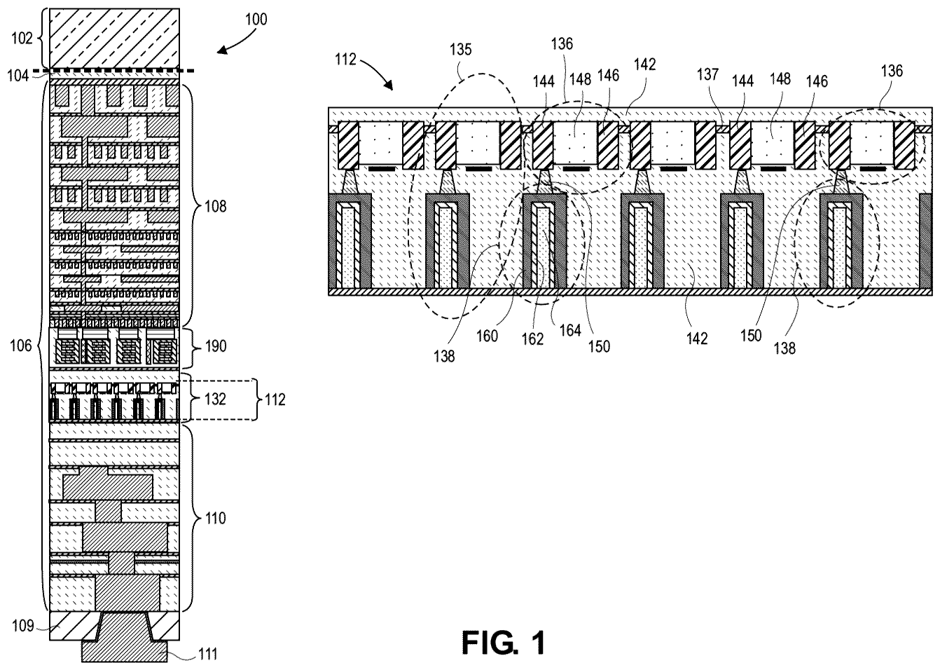

FIG. 1 shows cross-section side views of a diagram of a semiconductor package 100 that includes DRAM within a SiC layer or a GaN layer of the package, in accordance with various embodiments. Semiconductor package 100 includes a carrier wafer 102 that is bonded to a package 106 using an adhesive 104. The package 106 may include front side routing layers 108, which may include traces and conductive vias used to route low-voltage power and/or signals, e.g. 1-1.8 V. The package 106 may also include back side routing layers 110, which may include power routings and conductive vias.

In embodiments, a device layer 190 may be electrically coupled with and below the front side routing layers 108, and may include various devices, such as transistors, resistors, voltage regulators, or other devices. A SiC layer 132 may be between the device layer 190 and the back side routing layers 110. In embodiments, the back side routing layers 110 may also be SiC layers. In embodiments, a plurality of DRAM 112 may be formed within the SiC layer 132, and the plurality of DRAM 112 may be electrically coupled with the device layer 190, or may be electrically coupled with the back side routing layers 110.

In embodiments, a bump 111, which may include a solder ball or a copper pad, may be electrically coupled with the back side routing layers 110 to provide power from an outside source. In embodiments, the power may include high-voltage power greater than 1 kV. In embodiments, the bump 111 may be surrounded by a dielectric 109.

Diagram 112 shows an enlarged view of the plurality of DRAM 112 that are formed within the SiC layer 132. In embodiments, the SiC layer 132 may include SiC or any wide band gap material 142, such as GaN or some other material. The material may include indium phosphide (InP), gallium phosphide (GaP), phosphides, or antimonides. In embodiments, the wide band gap material 142 may be any material with a band gap of greater than two electron volts.

In embodiments, a DRAM 135 may include a transistor 136 that includes a drain 144, a source 146, and a gate 148. In embodiments, the transistor 136 may be electrically coupled with a capacitor 138. In embodiments, either the drain 144 or the source 146 may be electrically coupled with the capacitor 138 using electrical connection 150. In embodiments, at least some of the transistors 136 may be electrically coupled with each other using electrical connections 137.

In embodiments, the electrical connection 150 may be electrically coupled with a first plate 160, which may be referred to as a first electrode, of the capacitor 138. The second plate 164, which may referred to as a second electrode, may be proximate to the first plate 160, and separated by an insulator 162. In embodiments, the first plate 160 and the second plate 164 may be formed out of an electrically conductive material such as copper or some other metal. In embodiments, the insulator 162 may be an oxide, a dielectric, or a ferroelectric material. In embodiments, each of the capacitors 138 may be electrically isolated from each other. In embodiments, the capacitors 138 may be cylindrical, or may be planar, or may be some other shape.

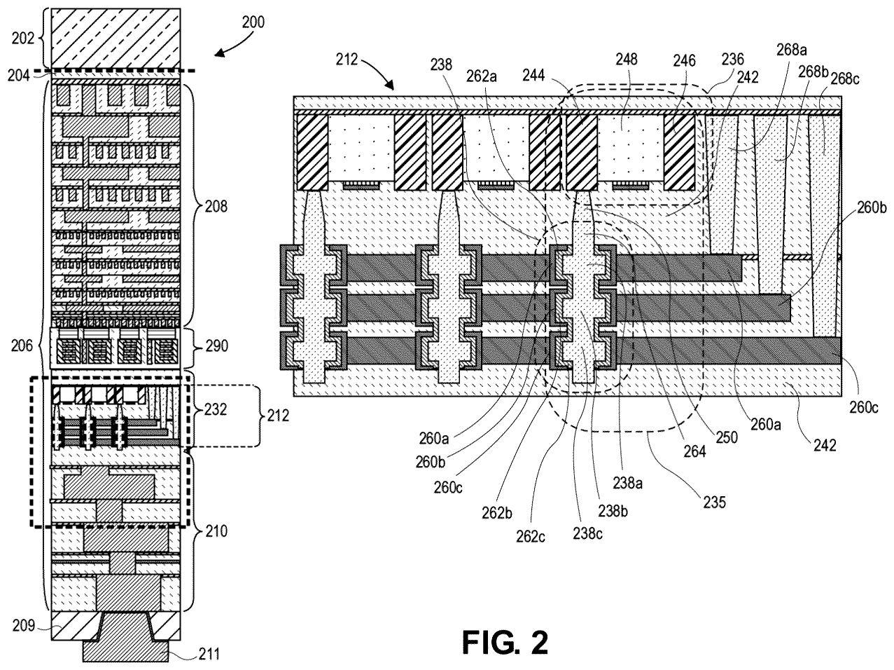

FIG. 2 shows cross-section side views of a diagram of a semiconductor package 200 that includes DRAM that includes three capacitors within a SiC layer or a GaN layer of the package, in accordance with various embodiments. Semiconductor package 200 includes a carrier wafer 202 that is bonded to a package 206 using an adhesive 204. The package 206 may include front side routing layers 208, which may include traces and conductive vias used to route low-voltage power and/or signals, e.g. 1-1.8 V. The package 206 may also include back side routing layers 210, which may include power routings and conductive vias.

In embodiments, a device layer 290 may be electrically coupled with and below the front side routing layers 208, and may include various devices, such as transistors, resistors, voltage regulators, or other devices. A SiC layer 232 may be between the device layer 290 and the back side routing layers 210. In embodiments, the back side routing layers 210 may also include SiC, or may include some other wide band gap material. In embodiments, a plurality of DRAM 212 may be formed within the SiC layer 232. In embodiments, the plurality of DRAM 212 may be electrically coupled with the device layer 290, or may be coupled with the back side routing layers 210.

In embodiments, a bump 211, which may include a solder ball or a copper pad, may be electrically coupled with the back side routing layers 210 to provide power from an outside source. In embodiments, the power may include high-voltage power greater than 1 kV. In embodiments, the bump 211 may be surrounded by a dielectric 209.

Diagram 212 shows an enlarged view of the plurality of DRAM 212 that are formed within the SiC layer 232. In embodiments, the SiC layer 232 may include any wide band gap material, such as GaN or some other material, which may include InP, GaP, phosphides, or antimonides. In embodiments, the wide band gap material may be any material with a band gap of greater than two electron volts.

In embodiments, a DRAM 235 may include a transistor 236 that includes a drain 244, a source 246, and a gate 248. In embodiments, the transistor 236 may be electrically coupled with a plurality of capacitors 238. In embodiments, either the drain 244 or the source 246 may be electrically coupled with the plurality of capacitors 238 using electrical connection 250.

The electrical connection 250 may be coupled with a second plate 264, which may be referred to as a second electrode, which is shared among the capacitors 238a, 238b, 238c. In embodiments, the second plate 264 may include a metal material, such as copper, that is electrically conductive. An insulator 262a, 262b, 262c may surround at least a portion of each of the capacitors 238a, 238b, 238c, and electrically isolate them from their respective first plates 260a, 260b, 260c, which may also be referred to as first electrodes. In embodiments, the first plates may include a metal material, such as copper, that is electrically conductive. Note that in embodiments, the first plates 260a, 260b, 260c are electrically isolated from each other.

In embodiments, each of the first plates 260a, 260b, 260c are electrically coupled, respectively, with electrical contacts 268a, 268b, 268c. During operation of the DRAM 235, a voltage resulting from the transistor 236 and a voltage resulting from one of the electrical contacts 268a, 268b, 268c may result in a value being stored or changed within the respective capacitors 238a, 238b, 238c. Note that in embodiments, a first plate of a capacitor of multiple DRAM 235 may be electrically coupled with each other.

In embodiments, because the DRAM 235 has been implemented in a wide band gap material 242, such as SiC or GaN, a higher voltage may be used for the DRAM 235 operation with less leakage during operation by suppressing band-to-band tunneling.

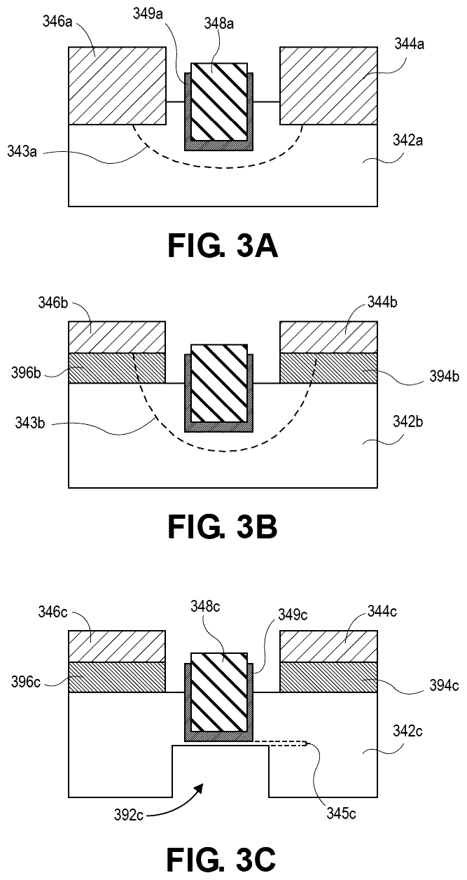

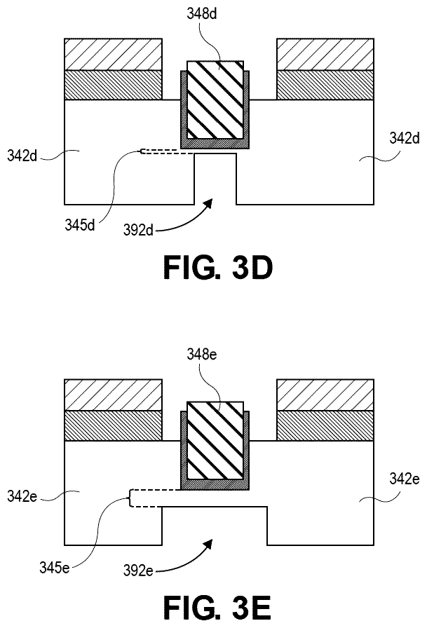

FIGS. 3A-3E show cross-section side views of various transistors that include additional layers between the transistor body and a source or drain contact, where the additional layers include SiC or GaN, in accordance with various embodiments. FIG. 3A shows a cross-section side view of a legacy transistor, which includes a body 342a, which may be a fin, with a gate oxide 349a on the body 342a, and a gate 348a, where the gate oxide 349a electrically isolates the gate 348a from the body 342a.

A source contact 346a is placed over a source region of the body 342a, and a drain contact 344a is placed over a drain region of the body 342a. In embodiments, the source contact 346a and the drain contact 344a may include a metal or some other electrically conductive material. As a result of this structure, an electrical gate length 343a is shown between the source contact 346a and the drain contact 344a. In embodiments, increasing the electrical gate length 343a using the techniques shown below may reduce the leakage of the transistor shown in FIG. 3A.

FIG. 3B shows a transistor that may be similar to the transistor shown in FIG. 3A. In embodiments, a layer 396b may be placed between the source contact 346b and a source region of the body 342b, and a layer 394b may be placed between the drain contact 344b and a drain region of the body 342b. In embodiments, the layer 396b and/or the layer 394b may be epitaxial layers. In embodiments, the body 342b may be a wide band gap material, such as GaN or SiC. In embodiments, the layer 394b or the layer 396b may be another layer of GaN or SiC, or may be another wide band gap material. In embodiments, the layer 394b or the layer 396b may be multiple layers. In embodiments, the layer 394b or the layer 396b may be grown on the body 342b, or may otherwise be formed on the body, for example using layer transfer techniques.

In this embodiment, the resulting electrical gate length 343b between the source contact 346b and the drain contact 344b is longer than the electrical gate length 343a. Because of the increased length of the electrical gate length 343a, the transistor of FIG. 3B may experience lower leakage than the transistor of FIG. 3A.

FIG. 3C shows a transistor that may be similar to the transistor shown in FIG. 3B. In this embodiment, a cavity 392c is formed in the body 342c underneath the gate 348c and the gate oxide 349c, to reduce the amount of material of the body 342c that is underneath the gate 348c, leaving portion of body 345c. In embodiments, the cavity 392c may be formed using techniques known in the art. In embodiments, a thickness of the portion of body 345c underneath the gate 348c may be less than a thickness of the body 342c under the source contact 346c or the drain contact 344c. As a result, the portion of the body 345c, during operation of the transistor of FIG. 3C, will improve electrostatic control of the channel by gate 348c.

FIG. 3D shows a transistor that may be similar to the transistor shown in FIG. 3C. In this embodiment, the cavity 392d in the portion of the body 345d is below the gate 348d, and is narrower than the cavity 392c of FIG. 3C. In this embodiment, the gate 348d overlaps the cavity 392d.

FIG. 3E shows a transistor that may be similar to the transistor shown in FIG. 3C. In this embodiment, the cavity 392e is shallower than the cavity 392c of FIG. 3C, and as a result the portion of the body 345e that is underneath the gate 348e will be thicker than the portion of the body 345c of FIG. 3C.

In embodiments, the transistors shown in FIG. 3A-3E are shown as finFET transistors. However, similar techniques may be used for transistors implemented as a field effect transistor, a nanowire transistor, a planar transistor, or a silicon on insulator transistor.

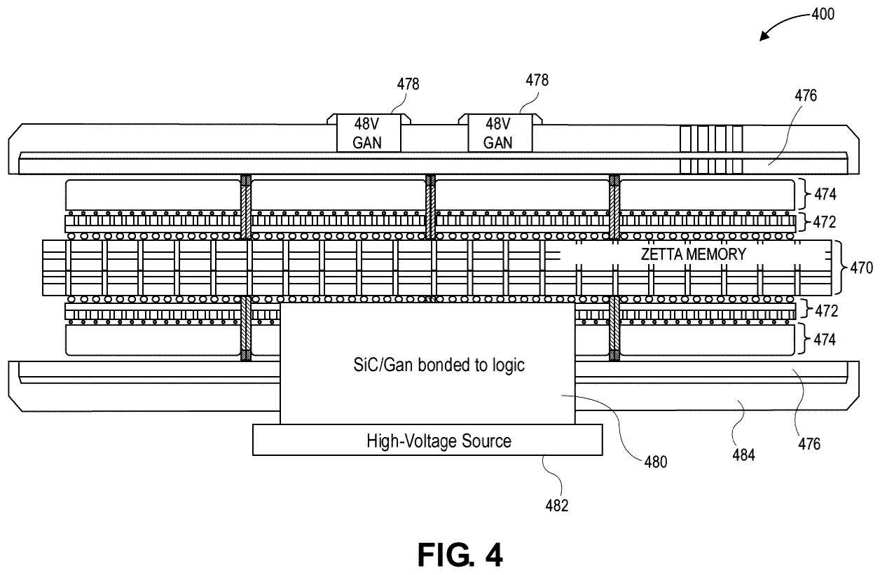

FIG. 4 illustrates a side view of a diagram of a wafer scale engine (WSE) that includes Zetta memory that is powered by high voltage input that is converted using devices within a SiC layer coupled with devices within a wide band gap layer, in accordance with various embodiments.

Embodiments described herein may be used to enable Zetta scale computing. Zetta scale computing may include an extremely large number of computing devices within a package. For example, the computing devices together may provide on the order of 10²¹ floating-point operations per second (FLOPS). In addition, Zetta scale computing may also involve digital storage in the form of memory, for example DRAM memory as described herein, on the order of a zettabyte, or 10²¹ bytes within the package. The large number of computing devices and memory devices within a package may be implemented as a WSE, which may involve an entire wafer or large portions of a wafer, or multiple wafers coupled with each other, that include repeating patterns of compute circuitry on the wafers. This may be done rather than fabricating independent dies that are subsequently stitched together.

One characteristic of a WSE is that it may include components that are tens of millimeters apart. Electrically coupling such components may involve a significant IR drop. In order to mitigate this IR drop, high voltages, for example on the order of 1 kV, may be used to route power from one area of the wafer to another, which may then be converted to 1-1.8V. In addition, a high-voltage supply may be used to provide significantly more power to a package. For example, a die on a wafer may consume on the order of 100 W. If there are 200 dies on a full wafer, that will requires 20 kW to power the entire wafer. And, if it is part of a WSE that may include multiple wafers bonded with each other, this power consumption will increase with each added wafer.

WSE 400 is an embodiment that includes a plurality of layers that may include a Zetta memory 470, which may include one or more wafers that may be coupled together, where each wafer includes a plurality of memory cells, such as the DRAM cells described in embodiments herein with respect to FIGS. 1-2, and transistors described in embodiments herein with respect to FIGS. 3A-3E.

In embodiments, interconnect layers 472 may be on the top and the bottom of the Zetta memory 470, and input/output (I/O) layers 474 may be coupled, respectively, with the interconnect layers 472. In embodiments, the I/O layers 474 may include photonics circuitry (not shown). In embodiments, a heat sink 476 may be thermally coupled with the I/O layers 474 and/or the Zetta memory 470. In embodiments, a casing 484 may at least partially surround the Zetta memory 470, the interconnect layers 472, the I/O layers 474, and/or the heat sink 476.

In embodiments, power supplies 478, which may be electrically coupled with voltage source of less than 1 kV, may include devices within a GaN layer, which may be used to step the high voltage source down to 1-1.8 V for use by the Zetta memory 470. In embodiments, a converter 480, which may include transistors within a GaN layer and transistors within a SiC layer that are coupled with each other to step down a voltage that may be greater than 1 kV from a high voltage source 482, down to 1-1.8 V, for use by the Zetta memory 470.

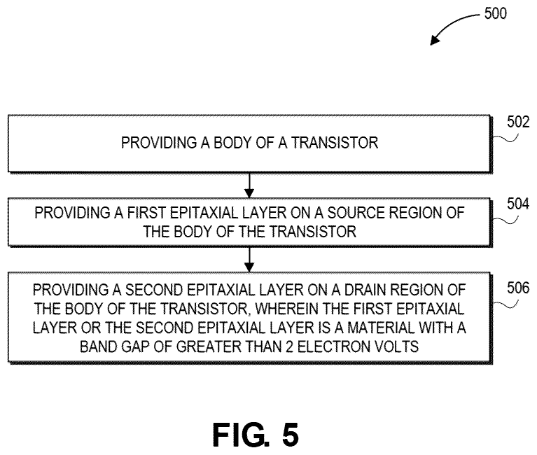

FIG. 5 illustrates an example process for creating a package that includes transistors that include additional layers between the transistor body and a source or drain contact, where the additional layers include SiC or GaN, in accordance with various embodiments. The process 500 may be performed using the processes, apparatus, systems, and/or techniques described herein, and in particular with respect to FIGS. 1-4.

At block 502, the process may include providing a body of a transistor. In embodiments, the body of a transistor may be similar to body 342a of FIG. 3A, body 342b of FIG. 3B, body 342c of FIG. 3C, body 342d of FIG. 3D, or body 342e of FIG. 3E.

At block 504, the process may further include providing a first epitaxial layer on a source region of the body of the transistor. In embodiments, the first epitaxial layer may be similar to layer 396b of FIG. 3B, or layer 396c of FIG. 3C.

At block 506, the process may further include providing a second epitaxial layer on a drain region of the body of the transistor, wherein the first epitaxial layer or the second epitaxial layer is a material with a band gap of greater than 2 electron volts. In embodiments, the second epitaxial layer may be similar to layer 394b of FIG. 3B, or layer 394c of FIG. 3C.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the spirit and scope of the present invention.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around-gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type work function metal or N-type work function metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

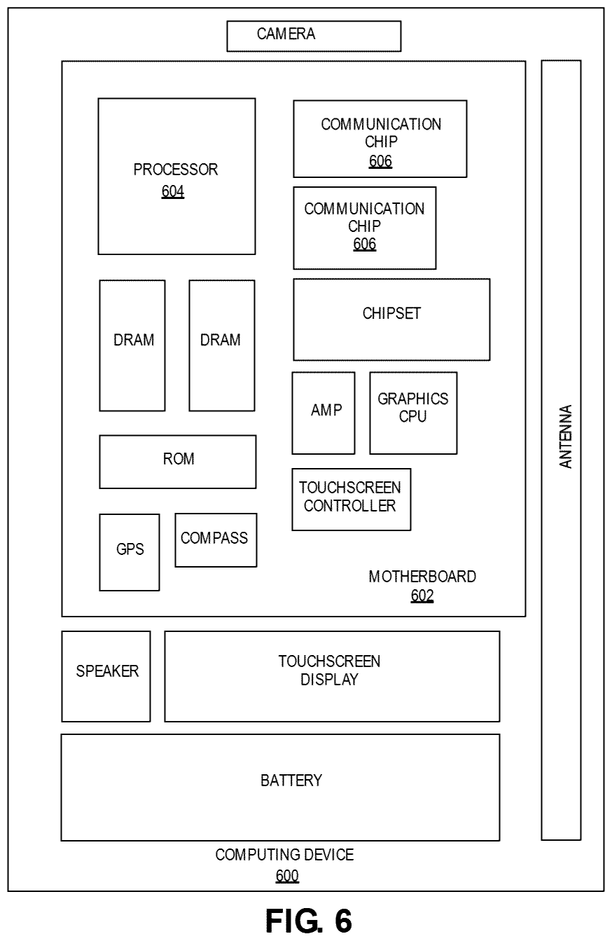

FIG. 6 illustrates a computing device 600 in accordance with one implementation of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip includes one or more devices, such as MOS-FET transistors built in accordance with implementations of the invention.

In further implementations, another component housed within the computing device 600 may contain an integrated circuit die that includes one or more devices, such as MOS-FET transistors built in accordance with implementations of the invention.

In various implementations, the computing device 600 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

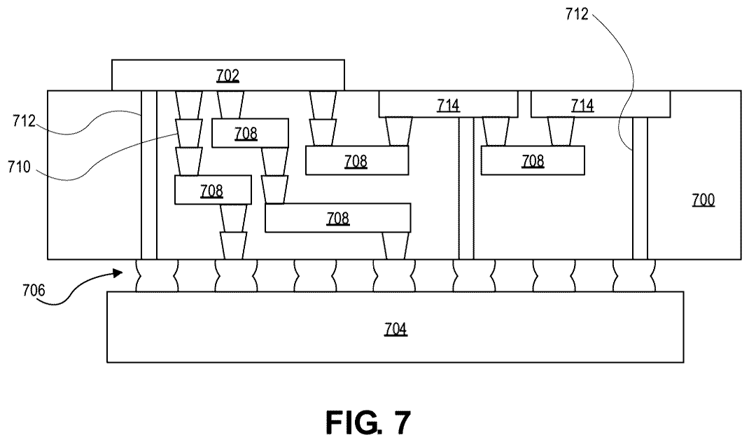

FIG. 7 illustrates an interposer 700 that includes one or more embodiments of the invention. The interposer 700 is an intervening substrate used to bridge a first substrate 702 to a second substrate 704. The first substrate 702 may be, for instance, an integrated circuit die. The second substrate 704 may be, for instance, a memory module, a computer motherboard, or another integrated circuit die. Generally, the purpose of an interposer 700 is to spread a connection to a wider pitch or to reroute a connection to a different connection. For example, an interposer 700 may couple an integrated circuit die to a ball grid array (BGA) 706 that can subsequently be coupled to the second substrate 704. In some embodiments, the first and second substrates 702/704 are attached to opposing sides of the interposer 700. In other embodiments, the first and second substrates 702/704 are attached to the same side of the interposer 700. And in further embodiments, three or more substrates are interconnected by way of the interposer 700.

The interposer 700 may be formed of an epoxy resin, a fiberglass-reinforced epoxy resin, a ceramic material, or a polymer material such as polyimide. In further implementations, the interposer 700 may be formed of alternate rigid or flexible materials that may include the same materials described above for use in a semiconductor substrate, such as silicon, germanium, and other group III-V and group IV materials.

The interposer 700 may include metal interconnects 708 and vias 710, including but not limited to through-silicon vias (TSVs) 712. The interposer 700 may further include embedded devices 714, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 700. In accordance with embodiments of the invention, apparatuses or processes disclosed herein may be used in the fabrication of interposer 700.

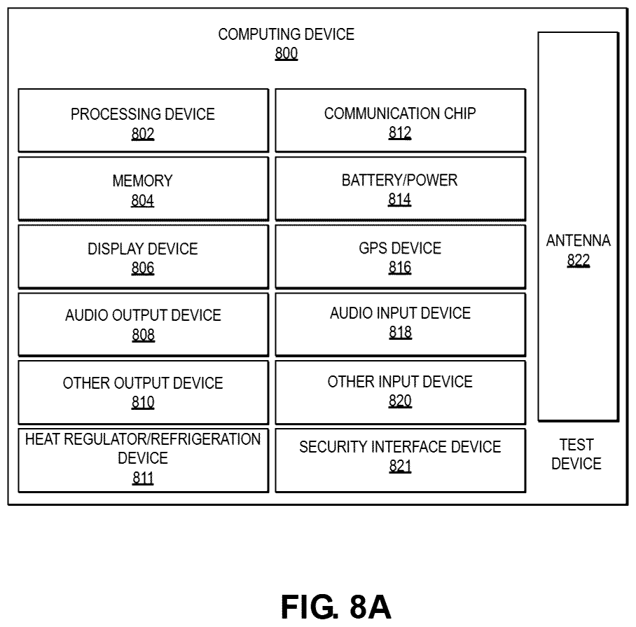

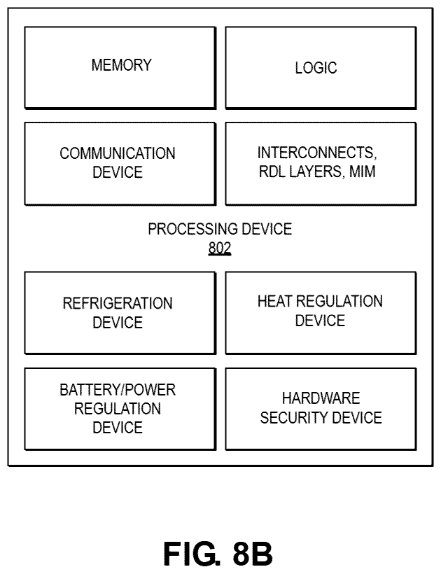

It is to be appreciated that structures described herein may be operated at a low temperature, e.g., in a range of −77 degrees Celsius to 0 degrees Celsius. In one embodiment, a heat regulator/refrigeration device is coupled to a common board having a device with structures such as those described herein coupled thereto, such as described below in association with FIG. 8A. In one embodiment, a heat regulator device and/or refrigeration device is included on a processing device having structures such as those described herein, such as described below in association with FIG. 8B.

FIG. 8A illustrates a computing device 800 in accordance with one implementation of an embodiment of the present disclosure. The computing device 800 houses a board. The board may include a number of components, including but not limited to a processing device 802. The computing device 800 can also include communication chip 812. In one embodiment, the processing device 802 is physically and electrically coupled to the board. In some implementations the communication chip 812 is also physically and electrically coupled to the board. In further implementations, the communication chip 812 is part of the processing device 802.

Depending on its applications, computing device 800 may include other components that may or may not be physically and electrically coupled to the board. These other components can include, but are not limited to, memory 804, such as volatile memory (e.g., DRAM), non-volatile memory (e.g., ROM), or flash memory, an antenna 822, a display device 806, a battery/power 814, an audio output device 808, an audio input device 818, a global positioning system (GPS) device 816, another output device 810 (such as video output), and other input device 820 (such as video input), a security interface device 821, and/or a test device. In one embodiment, a heat regulation/refrigeration device 811 is included and is coupled to the board, e.g., a device including actively cooled copper channels.

The communication chip 812 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 812 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 812. For instance, a first communication chip 812 may be dedicated to shorter range wireless communications such as Wi-Fi and Bluetooth and a second communication chip 812 may be dedicated to longer range wireless communications such as GPS, EDGE, GPRS, CDMA, WiMAX, LTE, Ev-DO, and others.

The processing device 802 of the computing device 800 can include an integrated circuit die in a package. The processing device 802 may include one or more structures, such as gate-all-around integrated circuit structures having ultra-high conductivity global routing, built in accordance with implementations of embodiments of the present disclosure. The term “processing device” may refer to any device or portion of a device that processes electronic data from registers and/or memory to transform that electronic data into other electronic data that may be stored in registers and/or memory.

FIG. 8B illustrates a processing device in accordance with one implementation of an embodiment of the present disclosure. Referring to FIG. 8B, an exemplary processing device 802 includes a memory region, a logic region, a communication device region, an interconnects and redistribution layer (RDL) and metal-insulator-metal (MIM) region, a refrigeration device region, a heat regulation device region, a batter/power regulation device region and a hardware security device region. In one embodiment, the refrigeration device region and/or the heat regulation device region is a region including actively cooled copper channels.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

The following paragraphs describe examples of various embodiments.

### Examples

Example 1 is a dynamic random-access memory (DRAM) comprising: a transistor that includes a source, a drain, and a body, wherein the body includes a selected one or more of: silicon (Si) and carbon (C) or gallium (Ga) and nitrogen (N); and a capacitor electrically coupled with the transistor.

Example 2 includes the DRAM of example 1, wherein the capacitor is within a layer that includes a selected one or more of: Si and C or Ga and N.

Example 3 includes the DRAM of examples 1 or 2, wherein the capacitor includes a first electrode, a second electrode, and an insulator, wherein the insulator electrically isolates the first electrode and the second electrode from each other, and wherein the first electrode is electrically coupled with the drain or with the source.

Example 4 includes the DRAM of example 3, wherein the capacitor includes a plurality of capacitors, wherein the first electrode of each of the plurality of capacitors are electrically coupled with each other.

Example 5 includes the DRAM of example 4, wherein the second electrode of the each of the plurality of capacitors are electrically isolated from each other.

Example 6 includes the DRAM of example 5, wherein the second electrode of each of the plurality of capacitors are electrically coupled with a corresponding electrical connection.

Example 7 includes the DRAM of examples 1, 2, 3, 4, 5, or 6, wherein the transistor is a selected one of: a field effect transistor, a nanowire transistor, a planar transistor, or a silicon on insulator transistor.

Example 8 includes the DRAM of examples 1, 2, 3, 4, 5, 6, or 7, wherein the insulator includes a selected one or more of: a dielectric, an oxide, or a ferroelectric.

Example 9 includes the DRAM of examples 1, 2, 3, 4, 5, 6, 7, or 8, wherein the DRAM is a portion of a wafer scale engine (WSE).

Example 10 is a transistor comprising: a body; a source, a drain, and a gate on the body; a first layer on the source, and a first contact on the first layer; a second layer on the drain, and a second contact on the second layer; and wherein the first layer or the second layer includes a material with a band gap that is greater than two electron volts.

Example 11 includes the transistor of example 10, wherein the first layer or the second layer is an epitaxial layer.

Example 12 includes the transistor of examples 10 or 11, wherein the first layer or the second layer includes a selected one or more of: silicon (Si), carbon (C), gallium (Ga), nitrogen (N), silicon carbide (SiC), gallium nitride (GaN), indium phosphide (InP), or gallium phosphide (GaP).

Example 13 includes the transistor of examples 10, 11, or 12, wherein a thickness of the body between a bottom of the gate and a bottom of the body below the gate is less than a thickness of the body between a bottom of the first layer and the a bottom of the body below the first layer.

Example 14 includes the transistor of examples 10, 11, 12, or 13, wherein the first layer on the drain and the second layer on the source increases an electrical gate length of the transistor.

Example 15 includes the transistor of examples 10, 11, 12, 13, or 14, wherein the transistor is a selected one of: a field effect transistor, a nanowire transistor, a planar transistor, or a silicon on insulator transistor.

Example 16 includes the transistor of examples 10, 11, 12, 13, 14, or 15, wherein the transistor is a portion of a wafer scale engine (WSE).

Example 17 is a method comprising: providing a body of a transistor; providing a first epitaxial layer on a source region of the body of the transistor; and providing a second epitaxial layer on a drain region of the body of the transistor, wherein the first epitaxial layer or the second epitaxial layer is a material with a band gap of greater than 2 electron volts.

Example 18 includes the method of example 17, wherein the first epitaxial layer or the second epitaxial layer includes a selected one or more of: silicon (Si), carbon (C), gallium (Ga), nitrogen (N), silicon carbide (SiC), gallium nitride (GaN), indium phosphide (InP), or gallium phosphide (GaP).

Example 19 includes the method of examples 17 or 18, further comprising providing a gate between the source region and the drain region.

Example 20 includes the method of example 19, further comprising removing a portion of the body that is beneath the gate.

What is claimed is:

1. A dynamic random-access memory (DRAM) comprising:
a transistor that includes a source, a drain, and a body, wherein the body includes a selected one or more of: silicon (Si) and carbon (C) or gallium (Ga) and nitrogen (N); and
a capacitor electrically coupled with the transistor.

2. The DRAM of claim 1, wherein the capacitor is within a layer that includes a selected one or more of: Si and C or Ga and N.

3. The DRAM of claim 1, wherein the capacitor includes a first electrode, a second electrode, and an insulator, wherein the insulator electrically isolates the first electrode and the second electrode from each other, and wherein the first electrode is electrically coupled with the drain or with the source.

4. The DRAM of claim 3, wherein the capacitor includes a plurality of capacitors, wherein the first electrode of each of the plurality of capacitors are electrically coupled with each other.

5. The DRAM of claim 4, wherein the second electrode of the each of the plurality of capacitors are electrically isolated from each other.

6. The DRAM of claim 5, wherein the second electrode of each of the plurality of capacitors are electrically coupled with a corresponding electrical connection.

7. The DRAM of claim 1, wherein the transistor is a selected one of: a field effect transistor, a nanowire transistor, a planar transistor, or a silicon on insulator transistor.

8. The DRAM of claim 1, wherein the insulator includes a selected one or more of: a dielectric, an oxide, or a ferroelectric.

9. The DRAM of claim 1, wherein the DRAM is a portion of a wafer scale engine (WSE).

10. A transistor comprising:
a body;
a source, a drain, and a gate on the body;
a first layer on the source, and a first contact on the first layer;
a second layer on the drain, and a second contact on the second layer; and
wherein the first layer or the second layer includes a material with a band gap that is greater than two electron volts.

11. The transistor of claim 10, wherein the first layer or the second layer is an epitaxial layer.

12. The transistor of claim 10, wherein the first layer or the second layer includes a selected one or more of: silicon (Si), carbon (C), gallium (Ga), nitrogen (N), silicon carbide (SiC), gallium nitride (GaN), indium phosphide (InP), or gallium phosphide (GaP).

13. The transistor of claim 10, wherein a thickness of the body between a bottom of the gate and a bottom of the body below the gate is less than a thickness of the body between a bottom of the first layer and the a bottom of the body below the first layer.

14. The transistor of claim 10, wherein the first layer on the drain and the second layer on the source increases an electrical gate length of the transistor.

15. The transistor of claim 10, wherein the transistor is a selected one of: a field effect transistor, a nanowire transistor, a planar transistor, or a silicon on insulator transistor.

16. The transistor of claim 10, wherein the transistor is a portion of a wafer scale engine (WSE).

17. A method comprising:
providing a body of a transistor;
providing a first epitaxial layer on a source region of the body of the transistor; and
providing a second epitaxial layer on a drain region of the body of the transistor, wherein the first epitaxial layer or the second epitaxial layer is a material with a band gap of greater than 2 electron volts.

18. The method of claim 17, wherein the first epitaxial layer or the second epitaxial layer includes a selected one or more of: silicon (Si), carbon (C), gallium (Ga), nitrogen (N), silicon carbide (SiC), gallium nitride (GaN), indium phosphide (InP), or gallium phosphide (GaP).

19. The method of claim 17, further comprising providing a gate between the source region and the drain region.

20. The method of claim 19, further comprising removing a portion of the body that is beneath the gate.
